(19) United States
(12) Patent Application Publication
(10) Pub. No.: US 2006/0280029 A1
(43) Pub. Date: Dec. 14, 2006

(54) Microfluidic mixer

(75) Inventors: Piotr Garstecki, Cambridge, MA (US); Michael A. Fischbach, Boston, MA (US); George M. Whitesides, Newton, MA (US)

Correspondence Address: WOLF GREENFIELD & SACKS, PC, FEDERAL RESERVE PLAZA, 600 ATLANTIC AVENUE, BOSTON, MA, 02210-2206, US

(73) Assignee: President and Fellows of Harvard College, Cambridge, MA (US)

(21) Appl. No.: 11/151,738

(22) Filed: Jun. 13, 2005

(51) Int. Cl. B01F 5/00; B81B 1/00

(52) U.S. Cl. 366/336; 366/341; 366/DIG. 2

(57) ABSTRACT

The present invention relates generally to microfluidic systems and, more specifically, to apparatuses and methods associated with mixing in microfluidic systems. In some embodiments, a mixer is constructed and arranged to mix at least a portion of a first and a second fluid component. The mixer may include a channel having an inlet that separates into at least two branches, the branches then recombining into a single outlet. In some cases, plugs of fluid (e.g., a gas) are flowed into the branches, which causes changes in resistance, and thus the amount of fluid flow, in each of the branches. The motion of the plugs through the network of branched channels can create unsteady mixing flows. For instance, for two fluid components, e.g., two streams of fluid flowing laminarly in the channel, these changes in resistance can cause the crossing of laminar streamlines of the fluid, which can lead to exponential stretching and folding of the interface between the two unmixed streams.

### FEDERALLY SPONSORED RESEARCH

Various aspects of the present invention were sponsored by the U.S. Department of Energy under award DE-FG02-OOER45852 and in part by the National Institute of Health (NIGMS) under award GM065364. The Government may have certain rights in the invention.

### FIELD OF INVENTION

The present invention relates generally to microfluidic systems and, more specifically, to apparatuses and methods associated with mixing in microfluidic systems.

### BACKGROUND

Fluidic systems, including microfluidic systems, have found application in a variety of fields. These systems that typically involve controlled fluid flow through one or more microfluidic channels can provide unique platforms useful in both research and production. For instance, one class of systems can be used for analyzing very small amounts of samples and reagents on chemical “chips” that include very small fluid channels and small reaction/analysis chambers. Microfluidic systems are currently being developed for genetic analysis, clinical diagnostics, drug screening, and environmental monitoring. These systems can handle liquid or gas samples on a small scale, and are generally compatible with chip-based substrates. The behavior of fluid flow in these small-scale systems, therefore, is central to their development.

Fluid flow in microfluidic systems is generally laminar, restricting mixing to diffusional transport which is typically slow. There have been several publications that have described mixers for microfluidic systems; for example, U.S. Pat. No. 6,065,864 describes a microelectromechanical system that mixes a fluid using predominately laminar flow. The microelectromechanical system includes a mixing chamber and a set of valves to establish the planar laminar flow in the mixing chamber. U.S. Pat. No. 6,854,338 describes devices which have micromachined ultrasonic transducers integrated into microchannels. The ultrasonic transducers generate and receive ultrasonic waves, and can be used to mix fluids. U.S. Patent Publication No. 2004/0262223 describes a mixer that functions by creating a transverse flow component in the fluid flowing within a channel without the use of moving mixing elements. The transverse flow component can be created by grooved features defined on the channel wall. Although these mixers may be suitable for some microfluidic systems, techniques used to fabricate many such mixers can be complicated, thereby limiting the mixers to being made in certain materials, and/or increasing the costs of fabricating a device. Advances in the field that could, for example, simplify fabrication and/or reduce costs would find application in a number of different fields.

### SUMMARY OF THE INVENTION

Apparatuses and methods associated with microfluidic systems and mixing in microfluidic systems are provided.

In one aspect, the invention provides a series of apparatuses. In one embodiment, a mixer constructed and arranged to mix at least a portion of a first and a second fluid component is provided. The mixer comprises a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system, fluidically connectable to the inlet channel, a source of the first fluid component, a source of the second fluid component, and a source of at least a first plug defined by a substance immiscible with the first and second fluid components which, when introduced into the inlet channel, causes the first plug to flow into the first or second branch of the second portion, wherein the mixer is constructed and arranged to mix the first and second fluid components to a greater extent in the outlet channel than in the inlet channel.

In another aspect, the invention provides a series of methods. In one embodiment, a method for mixing at least two fluid components is provided. The method comprises flowing the at least two fluid components in a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system, flowing a first plug defined by a first substance immiscible with the at least two fluid components in the first branch, flowing a second plug defined by a second substance immiscible with the at least two fluid components in the second branch, wherein the first and second substances can be the same or different, and at least in part via enhanced back pressure in either the first or second branch caused at least in part by a plug in one of the respective branches, causing at least a portion of the at least two fluid components to mix in the channel system such that the at least two fluid components are mixed to a greater extent in the outlet channel than in the inlet channel.

In another embodiment, a method for mixing at least two fluid components is provided. The method comprises flowing the at least two fluid components in a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system, changing resistance to fluid flow in the first branch, changing resistance to fluid flow in the second branch, wherein changing the resistance to fluid flow in the first and/or second branches causes at least a portion of the at least two fluid components to mix in the channel system, and whereby the at least two fluid components are mixed to a greater extent in the outlet channel than in the inlet channel.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A is an optical micrograph of a channel system, according to one embodiment of the present invention;

FIG. 1B is another optical micrograph of a channel system, according to another embodiment of the present invention;

FIGS. 1C-F illustrates normalized intensity profiles at various positions in the channel system of FIG. 1B, according to another embodiment of the present invention;

FIG. 2A is an optical micrograph of a flow focusing device, according to another embodiment of the present invention;

FIG. 2B is a schematic illustration of an immiscible plug in a rectangular capillary, according to another embodiment of the present invention;

FIG. 2C is a schematic illustration of a cross-section of the capillary shown in FIG. 2B, according to another embodiment of the present invention;

FIG. 3A is a schematic illustration of the streamlines of a fluid in a capillary, in the presence of plugs, according to another embodiment of the present invention;

FIG. 3B is a schematic illustration of a mixing unit of a mixer, according to another embodiment of the present invention;

FIG. 3C is a schematic illustration of a plug choosing a branch characterized by lower resistance, according to another embodiment of the present invention;

FIG. 3D is another schematic illustration of a plug choosing a branch characterized by lower resistance, according to another embodiment of the present invention;

FIG. 4 is a plot showing standard deviation of an intensity profile as a function of position along the channel network of a mixer, according to another embodiment of the present invention;

FIG. 5A are optical micrographs of the first and last mixing units of a mixer, according to another embodiment of the present invention;

FIG. 5B is a plot showing the profiles of the intensity of light across the width of a channel at different positions along a mixer, according to another embodiment of the present invention;

FIG. 5C is a plot showing standard deviation as a function of position along the channel network of a mixer for different conditions, according to another embodiment of the present invention;

FIGS. 6A-B are micrographs showing the fluorescent signals from pre-mixed solutions taken before a first branching unit and after a last branching unit, according to another embodiment of the present invention;

FIGS. 6C-D are micrographs showing the same positions as in FIGS. 6A-B for two streams that are mixed within a mixer, according to another embodiment of the present invention;

FIG. 6E is a plot of the mean intensity of the fluorescent signal obtained after each mixing unit of a mixer, according to another embodiment of the present invention;

FIG. 7A is a picture of a device incorporating a mixer, according to another embodiment of the present invention;

FIG. 7B is an optical micrograph of a network of channels of a device, according to another embodiment of the present invention;

FIG. 7C is an enlarged micrograph of a filter, according to another embodiment of the present invention; and

FIG. 7D is a micrograph of a mixer, according to another embodiment of the present invention.

### DETAILED DESCRIPTION

The present invention relates generally to microfluidic systems and, more specifically, to apparatuses and methods associated with mixing in microfluidic systems. In some embodiments, a mixer is constructed and arranged to mix at least a portion of a first and a second fluid component. The mixer may include a channel having an inlet channel portion that separates into at least two branches, the branches then recombining into a single outlet channel portion. In one arrangement, back pressure can be enhanced selectively in one of the branches (higher back pressure can exist in one branch relative to another branch), causing at least some mixing of fluid components within the channel system. Such variable back pressure can, for example, be provided in the following manner. In some cases, plugs of fluid (e.g., a gas) are flowed into the branches, which causes changes in resistance, and thus the amount of fluid flow, in each of the branches. The motion of the plugs through the network of branched channels can create unsteady mixing flows. For instance, for two fluid components, e.g., two streams of fluid flowing laminarly in the channel, these changes in resistance can cause the crossing of laminar streamlines of the fluid, which can lead to exponential stretching and folding of the interface between the two unmixed streams.

Apparatuses and methods of the invention can be used in a variety of settings. One such setting, described in more detail below, involves the mixing of reagents in a portable lab-on-chip solution phase assay.

“Plugs” as used herein, are described more fully below, as are various fluids and other materials which can be selected for use in the invention.

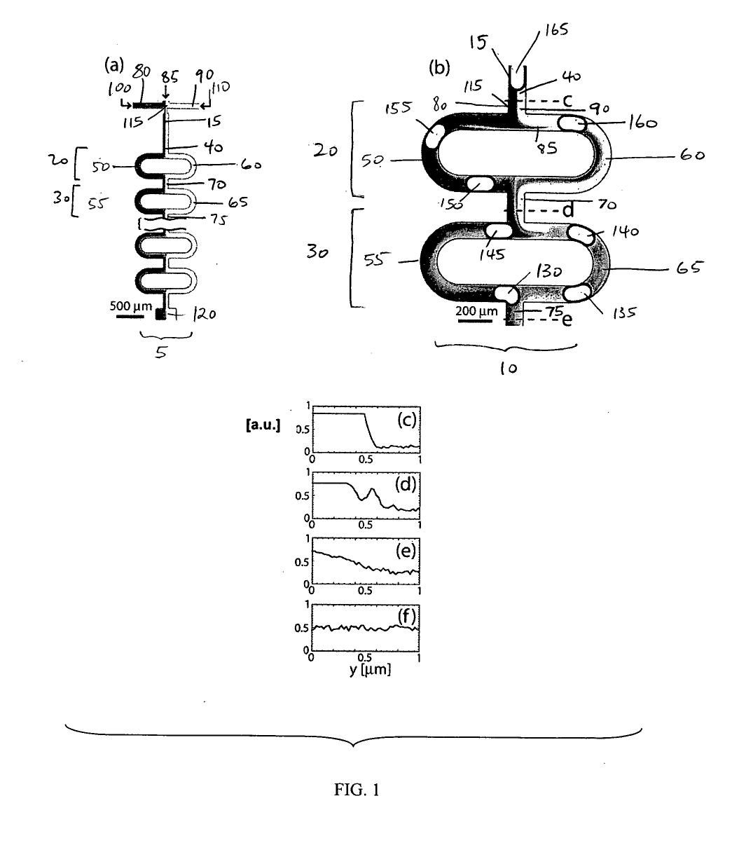

FIGS. 1A-B show an example of a channel design for a mixer, i.e., for mixing at least a portion of a first and a second fluid component, according to one embodiment of the invention. As illustrated in these figures, mixer 10 includes channel 15, which branches and forms mixing units 20 and 30. Unit 20 comprises a first channel portion 40 including an inlet channel that separates, in a second portion downstream of the first portion, into parallel branches 50 and 60. As shown in these figures, branches 50 and 60 having similar lengths and configurations; in other embodiments, however, parallel branches (i.e., branches within the same mixing unit) can have different lengths and/or configurations, as discussed in more detail below. Branches 50 and 60 recombine into an outlet channel defined by a third channel portion 70. Similarly, unit 30 comprises an inlet channel, also defined by third channel portion 70, that separates, in a fourth portion downstream of the third portion, into parallel branches 55 and 65. These branches recombine into an outlet channel defined by fifth channel portion 75. Branches 50 and 65 are diagonal to each other, as are branches 55 and 60.

As shown in FIG. 1A, first fluid 80 and second fluid 90 can be introduced into the channel system via inlets 100 and 110. Fluids typically flow from the inlet(s) (e.g., inlets 100 and 110) to the oulet(s) (e.g., outlet 120) of the channel system by creating a pressure differential between the inlet(s) and outlet(s), as discussed in further detail below. The first and second fluids can be introduced into the system such that they flow laminarly in first channel portion 40. In the absence of plugs in the branches (FIG. 1A), the first and second fluids may flow laminarly past junction 115, and they may, under appropriate conditions (those of ordinary skill in the art are aware of conditions that promote and/or allow laminar flow and when such flow will cease being laminar and involve mixing) continue to flow laminarly through many units, remaining laminar at outlet 120 without significant broadening at the interface. Mixing may be slow in this case because mixing occurs only by diffusion, the time for diffusion being directly related to the square of the distance. Typically, characteristic resistance times of the fluid in microfluidic devices are not large enough to ensure homogenization of reagents by diffusion.

In the presence of one or more plugs in the channel system (FIG. 1B), mixing can occur in the channels. In some instances, plugs of fluid can act as fluid resistors, as described in more detail below. Plugs 130-165 can be defined, for instance, by a fluid (e.g., a gas) immiscible with first fluid 80 and second fluid 90.

To understand how mixing occurs in FIG. 1B, consider the case of only three plugs, i.e., plugs 155, 160, and 165, flowing in channel 15. Plug 155 first flows into branch 50 (where the plug is selected to be a substance that will not divide at the intersection defining branches 50 and 60; the plug may flow into on of branches 50 or 60, selectively, randomly at first instance or may be directed into one or the other by factors including back pressure, fluid viscosity, or the like) and causes the resistance in that branch to be higher than the resistance in branch 60 via factors described more fully below. In other words, the presence of plug 155 in branch 50 causes an enhanced back pressure in branch 50. When the next plug, plug 160, flows into junction 115, it will be caused to flow into branch 60, since this branch has lower resistance to flow. Now, when plug 165 reaches junction 115, it will flow into branch 50, since branch 60 is currently more resistive to flow. A branch that has lower resistance causes not only the plug to flow in that branch, but also a portion of the fluid that follows the plug. For instance, the presence of plug 155 in branch 50 causes plug 160 to flow into branch 60, and portion 85 of first fluid 80 (black) also flows into branch 60 because of the lower resistance in this branch. This behavior causes the crossing of streamlines of the first and second fluids in the branches, which leads to mixing of the two fluids (i.e., the first and second fluids are mixed to a greater extent at the third channel portion 70 than at first channel portion 40). Mixing occurs because diffusional transport is facilitated by introducing flows that stretch and fold the first and second fluids; these stretches and folds enhance the gradients of concentrations of the first and second fluids and decrease the typical length scales of the unmixed streams exponentially in time.

The resistance (R), and therefore the flow rate (q), in each branch changes each time a plug enters or leaves a unit (R˜1/q). For example, if there are more plugs in branch 50 than branch 60 (i.e., assuming the volume of each plug is substantially the same), R₅₀>R₆₀, and less fluid flows into branch 50: q₅₀/q₆₀=R₆₀/R₅₀<1. If the first and second fluids are supplied at equal rates, some of the first fluid (black) flows into branch 60 (originally entirely clear). The ratio of the resistances in the parallel branches changes each time a plug enters or leaves the unit, so mixer 10 periodically sends volumes of the black fluid into the ‘clear’ branch, and vice versa.

By introducing a plurality of plugs and/or by including a plurality of mixing units into a mixer, further mixing can occur, as discussed in more detail below. For instance, a greater extent of mixing may be achieved at fifth channel portion 75 compared to third channel portion 70, and a greater extent of mixing achieved at third channel portion 70 relative to first channel portion 40. This concept is shown in FIGS. 1C-1F, which shows intensity profiles across the width of the channel at the indicated channel positions according to one set of measurements conducted in connection with a particular embodiment of a mixer described herein. In this particular experiment, homogenization of the first and second fluids (FIG. 1F) is achieved after six units of mixing.

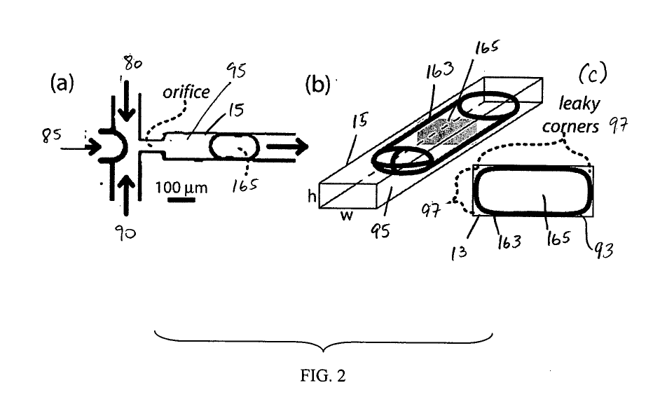

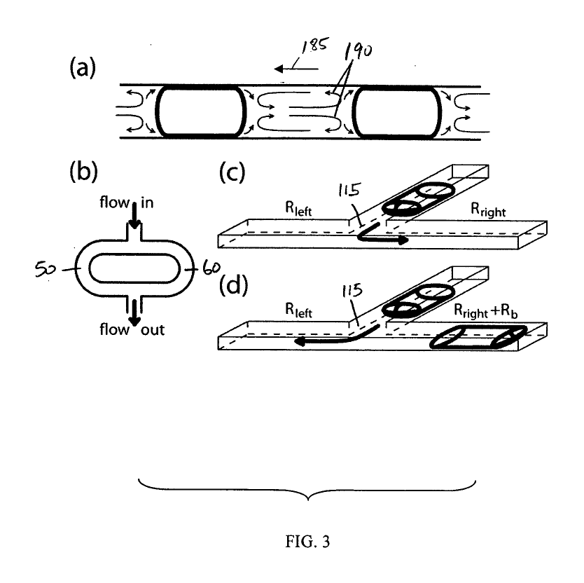

A further description of plug flow in a channel is now described in conjunction with FIG. 2B. As shown in FIG. 2B, upon selection of suitable materials for microfluidics and fluids (including plug fluids) large parts of the surface 163 of plug 165 are separated from wall 13 of channel 15 by a thin wetting film of continuous fluid 93, and the plug does not fill the cross-section of the channel entirely. The thin films of fluid between the plug and the walls of the channel can lead to increased viscous dissipation, and the speed u_{plug} of the plug does not match the mean velocity uₘₑₐₙ=Q/A of the host fluid (i.e., the fluid comprising the at least first and second fluid components). There are two consequences of this disparity. First, the flow of the host fluid can be divided into two contributions: the ‘plug’ flow Q_{plug}, which is flow at a mean velocity of the plug, Q_{plug}=Au_{plug}; and the flow in ‘leaky’ corners 97 (FIG. 2C), Q_{corner}=Q−Q_{plug}. When host fluid flows in direction 185, the portion of the host fluid that is confined between the plugs develops convection rolls 190 in the direction of the arrows (FIG. 3A); this has been previously described for mixing.

In the present invention, a second property of plug flow—increased resistance to flow—can be exploited for mixing fluids. As described above, a mixer can comprise a channel system including a single channel interrupted by units, which can include at least two branches running in parallel (FIG. 1B). For a Newtonian fluid, the resistance R_{S} to flow in capillaries at low to moderate Reynolds number may be described by the Hagen-Poiseuille equation, R_{S}=Δp/Q, where Δp is the pressure drop along the capillary of length L. R_{S} depends on the viscosity μ of the fluid and on the hydrodynamic radius rₕ of the channel (R_{S}=μL/rₕ⁴ for capillaries of nearly-square cross section, rₕ≈w). The pressure drop per unit length Δp* is a function of the externally controlled flow rate and the resistance of the channel, Δp*=R_{S}Q/L. A plug introduced into a rectangular capillary therefore generally increases its resistance to flow, and the pressure drop across the length l_{b} of the plug is larger than l_{b}Δp*. The presence of the plug in a capillary can be associated with a positive contribution to its resistance, R=R_{S}+nR_{b}, where R_{b} is the effective increase in resistance per plug and n is the number of plugs in the capillary.

In one embodiment, one design (FIG. 3B) of the mixer includes two branches, e.g., branches 50 and 60, that have equal lengths and cross-sectional areas. The resistances of the two branches can also be equal R₅₀(n=0)≈R₆₀(n=0). The pressure drop along each branch can be substantially the same, and therefore the rates of in-flow of the fluid into the two branches can be substantially the same: q₅₀/q₆₀=R₅₀/R₆₀≈1. When a plug reaches junction 115, it flows into the branch characterized by lower resistance, (i.e., the right channel in FIG. 3C). The presence of the plug increases resistance to flow in the right channel R_{right}=R_{right}(0)+R_{b}, under appropriate conditions and selection of materials and fluids, and the next plug flows into the left channel (FIG. 3D). The system exhibits memory; plugs remaining in the branching region “encode” the resistances of the two parallel branches. Therefore, the branch in which a plug flows can be determined by whether or not one or more preceding plugs is positioned in the branches, i.e., a plug generally will flow, given a choice between two branches, into the branch having fewer plugs downstream than the other branch.

In another embodiment, a mixer includes two parallel branches having substantially different lengths and/or cross-sectional areas. This difference in length and/or cross-sectional area between the first and second branches, assuming the same or similar materials and other parameters between the branches, causes a difference in resistance between the two branches (i.e., R_{left}(n=0)≠R_{right}(n=0)). For instance, a first branch having a longer length and/or a smaller cross-sectional area than a second branch will have a larger resistance than the second branch. This embodiment can cause a fluid, i.e., two laminar streams of fluid, to partition unevenly at the inlet of the branches, and larger amounts of fluid may flow into the channel having the lower resistance. Thus, the ratio of the amount of fluid flowing into one branch compared to a second, parallel branch can vary depending on the relative geometry of the two branches. For instance, greater than 1:1, greater than 2:1, greater than 5:1, or greater than 10:1 volumes of fluid can flow into one branch compared to another, parallel branch.

When a plug is flowed into a mixer comprising two parallel branches having different resistances in each branch, the direction in which a plug partitions not only depends on the number and/or size of the plug(s) preceding the plug, but also on the relative lengths and/or cross-sectional areas of the parallel branches. For instance, a first plug introduced into a mixing unit (i.e., having no other plugs in the branches of the unit) may flow into the branch having lower resistance to flow (i.e., the branch having the shortest length and/or having the largest cross-sectional area). The next plug flowed into the mixing unit may flow into the branch having the lowest sum of resistances, i.e., the resistance of the branch itself plus the resistance caused by any plugs positioned in that branch.

In one embodiment, a mixer comprises mixing units having branches that alternate between long and short branches. For instance, a first mixing unit can include a short branch on the left and a long branch on the right (i.e., R_{left}(n=0)<R_{right}(n=0)); the next mixing unit can include a long branch on the left and a short branch on the right (i.e., R_{left}(n=0)>R_{right}(n=0)), and so on. In some instances, branches positioned diagonally to each other have substantially the same length (i.e., long or short in the embodiment above). For small numbers of plugs in this system, this configuration of the mixer can lead to plugs alternating between left and right branches (i.e., flowing in the left branch of the first unit, the right branch of the second unit, and so on). In some cases, this system can allow creation of mixing flows using smaller numbers and/or volumes of plugs than a system in which the branches are substantially equal in length (and/or cross-sectional area).

In some embodiments, a mixing unit comprises more than two parallel branches. For instance, a mixer can comprise more than 1, more than 2, more than 5, more than 10, or more than 50 parallel branches. A small number of parallel branches (e.g., 2) may be suitable, for example, for devices requiring simple mixer design. In some cases, a mixer including mixing units having small numbers of parallel branches requires a plurality of mixing units to achieve homogenization of two fluid components. A large number of parallel branches (e.g., 50) can be useful for generating more complicated flows, which may have advantages in certain applications.

The branches of a mixing unit can be in the form of various shapes. FIG. 1 shows one embodiment in which all of the branched channels in the mixer are curved. This curvature can enhance mixing, and the absence of sharp corners in the branches can eliminate stagnation points and residual eddies. Branches having other shapes are also possible.

In some cases, a mixer comprises a plurality of mixing units that are in fluid communication with each other, e.g., the outlet of one mixer may flow into the inlet of another. For instance, the embodiment shown in FIG. 1A includes at least four mixing units. A mixer can comprise more than 1, more than 5, more than 10, more than 20, or more than 50 mixing units. The desired number of mixing units in a mixer can depend on factors such as the length of the branches and/or the frequency of plug flow. A mixer may comprise relatively few numbers of mixing units (e.g., less than 5) and can achieve homogenization of a fluid sample if, for instance, the branches are relatively long and/or if a large number of immiscible substances are flowed in the branches (i.e., such that the separation of the fluid sample is interrupted frequently by the immiscible substances). A mixer comprising a large number of mixing units (e.g., more than 20) may be suitable for units having shorter branches and/or for a mixer comprising a relatively small number of plugs.

In some instances, a mixer comprises a combination of channels having different dimensions, number of branches, and/or number of mixing units. For instance, a mixer having 10 mixing units may have some mixing units that have 2 branches in each unit, some that have 3 branches in each unit, and some of the branches can have different lengths and/or cross-sectional areas.

In some embodiments, mixing comprises flowing at least two fluid components in a mixing unit similar to that of FIG. 1B, and changing resistance to fluid flow in the first branch and/or second branch. Changing the resistance in the first and/or second branches can cause a portion of the at least two fluid components to mix in the channel system, whereby the at least two fluid components are mixed to a greater extent in an outlet channel than in an inlet channel of the mixing unit. Changing resistance can include flowing plugs of immiscible substances in the branches, or other methods of introducing temporal variations of resistance in the branches.

As described above, a plug, defined by one or more substances immiscible with one or more fluids used in the mixer which do or will surround the plug, can be used to change the resistance in a channel. As used here in, “immiscible” defines a relationship between two substances that are largely immiscible with respect to each other, but can be partially miscible. “Immiscible” substances, even if somewhat miscible with each other, will largely remain separate from each other in an observable division. For example, air and water meet this definition, in that a channel of the invention containing primarily an aqueous solution and some air will largely phase-separate into an aqueous portion and a plug (e.g., a gas bubble), even though air is slightly soluble in water and water vapor may be present in the air. In some cases, a plug comprises a liquid that is immiscible with the fluid sample (“fluid sample”, as used in this context means one or more fluids which do or will surround the plug in the mixer). For instance, if a fluid sample comprises an aqueous solution, then a plug may comprise an oil. If a fluid sample comprises an oil, a plug may comprises an aqueous solution. In other cases, a plug comprises a gas (e.g., air, oxygen, nitrogen, and argon) and the fluid sample may comprise an aqueous solution and/or an oil. In some instances, a plug is in solid form and may comprise, for example, a bead or an aggregate of particles or beads. In other instances, a plug comprises a gel.

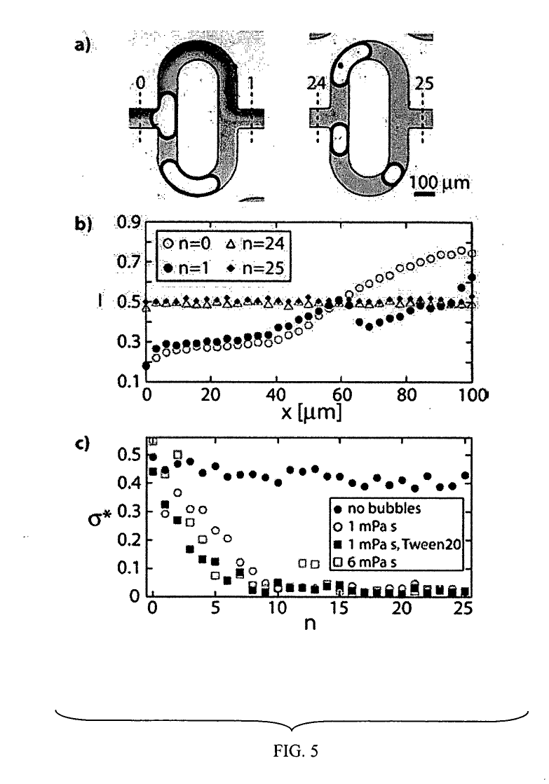

Plugs can have a range of different volumes. For example, a plug may have a volume of greater than 0.1 nL, greater than 1 nL, greater than 10 nL, greater than 0.1 μL, greater than 1 μL, greater than 10 μL, or greater than 100 μL, depending on variables such as the channel geometry and/or the material in which the plug is made. As shown in FIG. 1B, plugs 130-165 all have substantially the same volumes. In other embodiments, however, plugs can have substantially different volumes while positioned in the same mixer and/or mixing unit, i.e., as shown in FIG. 5B. For a mixer comprising plugs of different volumes, the resistance of a branch depends not only on the number of plugs in the branch, but also on the volumes of each plug in the branch.

Plugs can also have various sizes and/or shapes. For instance, a plug can have a cross sectional dimension of greater than 0.1 μm, greater than 1 μm, greater than 10 μm, greater than 100 μm, or greater than 250 μm. In some instances, the size and/or shape of a plug depends on its volume and/or the dimensions of the channel in which the plug is positioned. For example, a plug may have a more spherical shape in a cylindrical channel, or have a more rectangular shape in a rectangular channel. In another example, a plug can have an elongated shape in a narrow channel, but may have a spherical shape in a tall, wide channel. Therefore, in some cases, the plug can conform to the shape of its container, and the resistance of a channel can change depending on the size and/or shape of the plug.

In some embodiments, a mixer is used for mixing at least two fluid components. As shown in FIG. 1, a first fluid component can be a first stream of fluid and a second fluid component can be a second stream of fluid. The first and second streams, which may be the same or different fluids, can be flowed laminarly at the inlet to a mixing unit. In this case, mixing comprises the mixing of the two laminar stream of fluid.

Various types of fluid components can be mixed using the mixer. In some cases, fluid components comprise binding partners, molecules that can undergo binding with a particular molecule. For instance, Protein A is a binding partner of the biological molecule IgG, and vice versa. Likewise, an antibody is a binding partner to its antigen, and vice versa. In other cases, fluid components can comprise chemicals, cells, beads, buffers, diluents, and the like.

A mixer can also be used to mix more than two fluid components. For instance, the mixer can be used to mix more than 1, more than 2, more than 5, more than 10, or more than 50 fluid components, i.e., depending on the application.

A mixer may also comprise sources of fluid components that are fluidically connectable to inlet channel 40. For instance, as shown in FIG. 1A, sources of the first and second fluid components may comprise inlets 100 and 110, which are in fluid communication with inlet channel 40. In some cases, a source (e.g., inlet 85) of one or more plugs may also be in fluid communication with inlet channel 40. Introduction of these sources into inlet channel 40 may cause the one or more plugs to flow into a mixing unit. In some embodiments, each of the sources are contained in separate containers such as channels, wells, chambers, reservoirs, and the like. These containers may be enclosed, open, covered, or uncovered, etc.

Those of ordinary skill in the art, upon reading the present disclosure, will understand how to establish microfluidic or other fluid channel networks and to introduce plugs into those channel networks in accordance with the invention. Those of ordinary skill in the art will be able to select fluids and systems that will establish laminar flow and/or will be able to recognize when, in a particular fluid system under particular conditions, laminar flow will exist inherently, and where mixing of such fluids can be achieved as described herein. Fluids can be flowed in a device using a variety of methods. Generally, a pressure differential between an inlet and an outlet causes fluid flow in the direction of the inlet to the outlet. In one embodiment, the flow rate of a fluid in a channel (e.g., channel 15 of FIG. 1A) is controlled by moderating the rates of flow of the fluids in inlets 85, 100, and 110. In some instances, a pressure (i.e., greater than atmospheric pressure) can be applied to the inlets using a syringe pump, syringe (i.e., manually), valve, or other apparatus. Gravity may also be used to generate flow. In another embodiment, the flow rate can be controlled by applying a pressure (i.e., less than atmospheric pressure) to an outlet of the network of channels (e.g., outlet 120). In one particular embodiment, a single source of pressure (i.e., less than atmospheric pressure) is applied to the outlet of the network of channels to establish fluid flow.

Different methods can be used to generating plugs for the mixer. In one embodiment, formation of plugs is controlled by moderating the rates of flow of the fluids in inlets 85, 100, and 110. For instance, pressures (i.e., greater than atmospheric pressure) can be applied to inlets 85, 100, and/or 110 to generate plugs. In another embodiment, formation of plugs can be obtained by applying a pressure less than atmospheric pressure (i.e., a vacuum) to an outlet of the network of channels (e.g., outlet 120 of FIG. 1A). In one particular embodiment, a single source of pressure (i.e., less than atmospheric pressure) is applied to the outlet of the network of channels to generate plugs.

Fluids and/or plugs can be flowed at different flow rates depending on the amount of pressure applied to the inlets and/or outlets of the device, and/or by regulating other components of the device, such as valves, as discussed in more detail below. For instance, a fluid and/or a plug may be flowed at a rate of greater than 0.001 μL/s, greater than 0.01 μL/s, greater than 0.1 μL/s, greater than 1 μL/s, greater than 10 μL/s, greater than 100 μL/s, greater than 1 mL/s, or greater. In some embodiments, the rate of flow of fluid influences the rate of plug formation. In other embodiments, at least two fluid components are flowed into the device at different flow rates, thus causing unequal partitioning of fluids at a junction to a mixing unit.

The number of plugs in a mixer, and thus the distance between plugs in a channel, can vary. The number of plugs in a mixer at each point in time will depend on factors such as the number of mixing units, the length of the branches, the size of the plugs, the flow rate, rate of introduction of plugs, etc. A mixer may have greater than or equal to 1, greater than or equal to 2, greater than or equal to 5, greater than or equal to 10, greater than or equal to 20, greater than or equal to 50, greater than or equal to 100, greater than or equal to 500, or greater than or equal to 1000 plugs in the system. A mixer may comprise relatively few plugs (e.g., less than 10) for situations where mixing is aided by other factors. For instance, as discussed above, mixing units having branches that alternate between long and short branches can aid in mixing, and relatively few plugs may be required for these configurations. In other cases, a large number (e.g., greater than 100) of plugs in a mixer is suitable. Large numbers of plugs can result in relatively short distances between plugs, and can cause more frequent crossings of streamlines.

The mixer can be compatible with a range of viscosities. For instance, the mixer can be used to mix biological fluids that are of potential interest: human blood serum, which has a viscosity of 2 mPa s and has twice the viscosity of water (1 mPa s), and whole blood, a strongly non-Newtonian, shear-thickening fluid. The mixer can also be used to mix a glycerol solution, which can have a viscosity equivalent to the viscosity of blood at low shear rates—approximately 5-6 mPa s. The mixer can be used to mix fluids having other ranges of viscosity as well (e.g., μ=10 mPa s and higher).

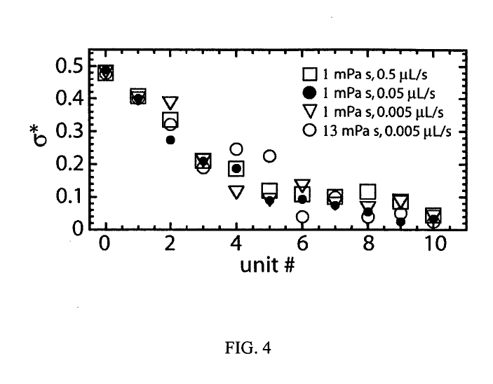

The degree and/or efficiency of mixing in a mixer can depend on a variety of factors, including the channel geometries (i.e., of the branches), the number of mixing units, the volume/size of the plug, and the number of plugs in the system (i.e., the distance between plugs). The efficiency of the mixer does not change significantly, however, over a wide range of the rates of flow and/or the viscosity of the host fluid, in some embodiments. This is illustrated in FIG. 4, which shows standard deviation of the intensity profile measured as a function of position along the channel network of device 10. Unit index equal to zero corresponds to the profile obtained upstream of the first unit (as in FIG. 1C), σ*=0.5 signifies unmixed streams, while σ*=0 corresponds to fully homogenized liquid. Behavior of the system does not change over a wide range of the rates of flow Qε(5×10⁻³, 0.5) μL/s and viscosity, με(1,13) mPa s of the host fluid. This is consistent with the model assuming exponential increase of the area of interface between the two liquid streams, as outlined in Example 2. The volume fraction of the plugs (i.e., the volume of the plugs compared to the volume of the host fluid) in this particular channel network was φ≈0.5, 0.2, 0.15 and 0.2 for Q=0.5, 0.05, 0.005 μL/s (μ=0.9 mPa s) and Q=0.005 μL/s (μ=0.9 mPa s) respectively.

In some cases, the efficiency of mixing does not depend on the presence of surfactants (i.e., present in the fluid sample), as shown in FIG. 5. Thus, a mixer can mix a first sample, which contains significant amounts of surfactant, and the same mixer can mix a second sample, which does not contain a significant amount of surfactant, and the efficiency of mixing in both cases can be similar. This characteristic of the mixer is important for physiological samples, many of which contain surface-active ingredients that might, in principle, interfere with the operation of the mixer. This can also be true for specific diagnostic applications that require the use of surfactants, i.e., to prevent adsorption of proteins to the gas-liquid interface.

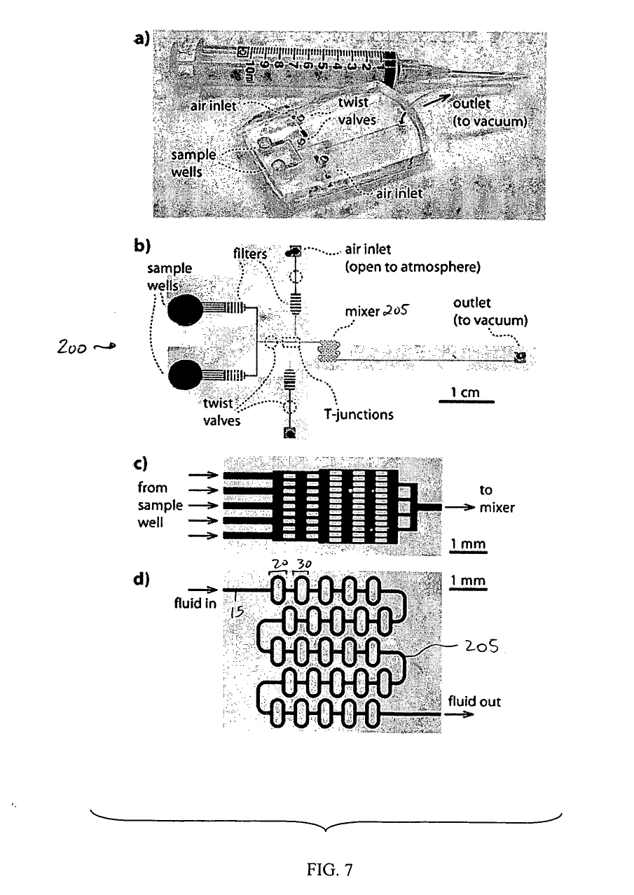

Mixers can be combined with other components such as filters, valves, and pumps, to generate functional devices (i.e., microfluidic devices). In one embodiment, as shown in FIG. 7, mixer 205 is integrated into a portable microfluidic platform, e.g., device 200. Mixer 205 comprises several mixing units (e.g., 20 and 30) fluidically connected to each other by channel 15. As shown in this example, channel 15 is arranged in a serpentine configuration; this configuration may be advantageous for forming a compact mixer. In other embodiments, mixing units and/or channel 15 can be arranged in other configurations, such as linear, curved (i.e., parabolic or circular), or other arrangements.

Devices described herein can be easy to fabricate as they can, if desired, be formed via single step lithography, and may be simple in use, i.e., requiring only a single source of low quality vacuum (i.e., using a syringe) and is independent of any bulky equipment. The device can operate over a range of viscosities encompassing those of physiological fluids. The T-junction geometry can be suitable for formation of plugs by application of a pressure less than atmospheric pressure to the outlet of the device. In some cases, the plugs homogenize residence times and mix the continuous liquid. It should be possible to integrate additional components (e.g., for analytic purposes) into the device. Plugs can be efficiently separated from the liquid with the use of capillary pressure. The residence times of the analytes—a parameter important in many biological assays—can be tuned (i.e., either in the fabrication process or directly in the field) by adjusting the imbedded valves (e.g., TWIST valves). In some embodiments, the device functions efficiently both in the presence or absence of surface-active agents, making it applicable for diagnostic assays involving proteins. Such devices can be an important tool for enabling sophisticated micro-flow engineering and diagnostic techniques to resource poor settings and first response situations.

As used herein, a channel (including a branch, inlet channel, and outlet channel) is a feature on or in an article (substrate) that at least partially directs the flow of a fluid. The channel can have any cross-sectional shape (circular, oval, triangular, irregular, square or rectangular, or the like) and can be covered or uncovered, so long as it can direct the flow of fluids, plugs, and enhance mixing of fluids by plugs. In embodiments where it is completely covered, at least one portion of the channel can have a cross-section that is completely enclosed, or the entire channel may be completely enclosed along its entire length with the exception of its inlet(s) and outlet(s). An open channel generally will include characteristics that facilitate control over fluid transport, e.g., structural characteristics (an elongated indentation) and/or physical or chemical characteristics (hydrophobicity vs. hydrophilicity) or other characteristics that can exert a force (e.g., a containing force) on a fluid.

Most fluid channels in components of the invention have maximum cross-sectional dimensions less than 2 mm, and in some cases, less than 1 mm. In one set of embodiments, all fluid channels containing embodiments of the invention are microfluidic or have a largest cross sectional dimension of no more than 2 mm or 1 mm. In another embodiment, the fluid channels may be formed in part by a single component (e.g., an etched substrate or molded unit). Of course, larger channels, tubes, chambers, reservoirs, etc. can be used to store fluids in bulk and to deliver fluids to components of the invention. In one set of embodiments, the maximum cross-sectional dimension of the channel(s) containing embodiments of the invention are less than 500 microns, less than 200 microns, less than 100 microns, less than 50 microns, or less than 25 microns. In some cases the dimensions of the channel may be chosen such that fluid is able to freely flow through the article or substrate. The dimensions of the channel may also be chosen, for example, to allow a certain volumetric or linear flow rate of fluid in the channel. Of course, the number of channels and the shape of the channels can be varied by any method known to those of ordinary skill in the art. In some cases, more than one channel or capillary may be used. For example, two or more channels may be used, where they are positioned inside each other, positioned adjacent to each other, positioned to intersect with each other, etc.

A mixer can be fabricated of any material suitable for forming a microchannel. Non-limiting examples of materials include polymers (e.g., polystyrene, polycarbonate, poly(dimethylsiloxane)), glass, and silicon. Those of ordinary skill in the art can readily select a suitable material based upon e.g., its rigidity, its inertness to (i.e., freedom from degradation by) a fluid to be passed through it, its robustness at a temperature at which a particular device is to be used, and/or its transparency/opacity to light (i.e., in the ultraviolet and visible regions).

In some instances, the mixer is comprised of a combination of two or more materials, such as the ones listed above. For instance, the channels of the device may be formed in a first material (e.g., poly(dimethylsiloxane)), and a substrate that is formed in a second material (e.g., polystyrene) may be used as the base to seal the channels.

In some cases, channels, or portions of channels, can be made hydrophilic or hydrophobic by various methods known to those of ordinary skill in the art, such as by passivating surfaces with certain molecules (e.g., proteins). For devices made in siloxanes (e.g., PDMS) and/or other suitable polymers, a method for maintaining the hydrophilicity/hydrophobicity of a channel may comprise storing them in hermetic, humidified containers.

One procedure for fabricating a mixers and/or channels in a structure is described below. It should be understood that this is by way of example only, and those of ordinary skill in the art will know of additional techniques suitable for forming microfluidic structures, for instance, as discussed in U.S. Pat. No. 6,719,868, which is incorporated herein by reference.

In one embodiment, a microfluidic channel and/or components of a device may be made by applying a standard molding article against an appropriate master. For example, microchannels can be made in PDMS by casting PDMS prepolymer (Sylgard 184, Dow Corning) onto a patterned photoresist surface relief (a master) generated by photolithography. The pattern of photoresist may comprise the channels having the desired dimensions. After curing for 2 h at 65° C., the polymer can be removed from the master to give a free-standing PDMS mold with microchannels embossed on its surface.

Inlets and/or outlets can be cut out through the thickness of the PDMS slab. To form substantially enclosed microchannels, the microfluidic channels may be sealed in the following way. First, the PDMS mold and a flat slab of PDMS (or any other suitable material) can be placed in a plasma oxidation chamber and oxidized for 1 minute. The PDMS structure can then be placed on the PDMS slab with the surface relief in contact with the slab. The irreversible seal is a result of the formation of bridging siloxane bonds (Si—O—Si) between the two substrates that result from a condensation reaction between silanol (SiOH) groups that are present at both surfaces after plasma oxidation.

The following examples are intended to illustrate certain embodiments of the present invention, but are not to be construed as limiting and do not exemplify the full scope of the invention.

### EXAMPLE 1

This example shows the formation of plugs in a microfluidic device. Plugs of gas were formed using a flow focusing (FF) geometry (FIG. 2A) in a device prepared in poly(dimethylsiloxane). Flow focusing arrangements, and systems analogous to flow focusing that can be useful in the present invention are known to those of ordinary skill in the art and described in International Patent Publication WO 04/002627, published Jan. 8, 2004 by Stone, et al., International Publication WO/04/091763, published Oct. 28, 2004, by Link, et al., and other locations. The FF region (FIG. 2A) comprises two inlet channels for the two liquid streams (water/glycerol/Tween20 solutions delivered from a syringe pump, Harvard Apparatus PhD2000) and a single inlet channel for the gaseous phase (nitrogen from a pressurized tank). The gaseous thread periodically enters the orifice, breaks, and releases plugs into the outlet channel. The volume of the plug and the volume fraction of the gaseous phase can be controlled by adjusting the pressure p applied to the gas stream and the total rate of flow Q of the two liquid streams. Two inlets were used for the continuous fluid to supply the liquids to be mixed. In most experiments, the liquids contained 2% (w/w) Tween 20 surfactant, and for visualization purposes, one of the liquids contained dye (Waterman black ink). The flow rates of the transparent liquid qₜ and the black liquid q_{b} were equal, qₜ=q_{b}=Q/2.

### EXAMPLE 2

In order to assess whether the flow in mixer 10 of FIG. 1B satisfies the criteria of a properly designed mixer, an estimate was performed and verified by quantifying the concentration profiles along the channel of mixer. It was postulated that each branching unit doubles the area of interface between the two fluids 80 and 90 and the overall increase is exponential in the distance traveled downstream. The number of units needed to mix the two fluids was estimated by comparing the average distance between two black-clear interfaces dᵢₙₜₑᵣ˜w2^{-l/a} (where l is the length traveled downstream and a is the arc length of the arm in the branching section) and the diffusional length scale d_{diff}=(t D)^{1/2} (with time t related to distance l=tQ/w² traveled downstream). Assuming the fluids are mixed to homogeneity at distance lₘᵢₓ at which dᵢₙₜₑᵣ=d_{diff}, which leads to lₘᵢₓ/a=(2 ln 2)⁻¹(ln Pe−ln(lₘᵢₓ/w)) with Pe=Q/Dw=10⁵ for Q=1 μL/s, D=10⁻⁶ cm²/s and w=100 μm. If the term ln(lₘᵢₓ/w) is neglected, which is small in comparison to In Pe, lₘᵢₓ/a≈8 is obtained. In accordance with the assumption of exponential folding, this prediction (lₘᵢₓ/a) is largely insensitive to the initial value of the Peclet number: lₘᵢₓ/a≈7 for Pe=10⁴ and lₘᵢₓ/a≈10 (Pe=10⁶).

Experiments were performed with a range of flow rates, Qε(5×10⁻³, 0.5) μL/s, and two different viscosities of the host fluid με(0.9, 13) mPa s. Intensity profiles I(y) of light across the channel were measured after each mixing unit (FIG. 3c-f), and mixing was quantified by dividing the standard deviation of I(y) by its mean value: σ*=σ(I(y))/<I((y)>. A value of σ*=0.5 indicates unmixed streams, and σ*=0 signifies complete mixing. In agreement with the estimates, homogenization of the two aqueous streams was observed within ten branching units. The system behaves similarly over the whole range of Reynolds (Reε(10⁻², 10²)) and Peclet (Peε(10³, 10⁶)) numbers tested in the experiments (FIG. 4). These results confirm the assumption of exponential folding of the liquid domains, and they demonstrate the efficiency of the branched channel mixer. The device was observed to mix efficiently for volume fractions of the gaseous phase φ>0.1, below which value mixing efficiency can drop in some cases. This experiment shows that the efficiency of the mixer does not change significantly over a wide range of the rates of flow and/or the viscosity of the host fluid.

### EXAMPLE 3

The efficiency of mixing and applicability of the mixer to fluids of varied viscosity and with and without surfactant was tested. Experiments were performed in a mixer comprising 25 units of mixing (n) as shown in FIGS. 5A-C. To visualize mixing, two streams of aqueous solutions of glycerol were used, one of which was dyed with a black ink (Waterman). In the absence of plugs, the two fluids flow down the channels laminarly with only small diffusional mixing at the black-clear interface. When air is allowed to flow into the channel and break into plugs, the gaseous plugs mix the fluids. Mixing was quantified by taking intensity profiles I(d) across the main channel before the mixer and after each of branching sections. The intensity can acquire any value between 0 (corresponding to the original—unmixed—‘black’ solution) and 1 (original ‘clear’ solution). A normalized standard deviation σ*=σ(I(d))/<I(d)> of the intensity profile I(d) was calculated. A value of σ*=0 corresponds to ideally homogeneous distribution of dye, while σ*=0.5 signifies two separate stream of original solutions. FIG. 5A shows optical micrographs of the first and the last branching sections of the mixer (experiment with 1 mPa s aqueous solutions of surfactant). The dashed lines show the positions at which we acquired the profiles of the intensity of light across the channel (i.e., from top to bottom in FIG. 5A). The numbers indicate the number of the branching section after which the profile was taken. These profiles are shown in FIG. 5B. Homogenization of the two liquid streams was quantified by the normalized standard deviation of the intensity profiles. FIG. 5C shows the evolution of σ* as a function of the position in the mixer (number of branching sections passed) for four different conditions—no plugs (●), the aqueous solutions without (∘, μ≈1 mPa s) and with (▪, μ≈1 mPa s) surfactant, and the 50% w/w solutions of glycerol (□,μ≈6 mPa s). The rapid decay of σ from ˜0.5 before the first branching section to ˜0 after approximately 10 branching sections indicates efficient mixing of the all of the liquids tested in the experiments. This experiment also shows that the efficiency of the mixer does not change significantly over different amounts of surfactant in the host fluid.

### EXAMPLE 4

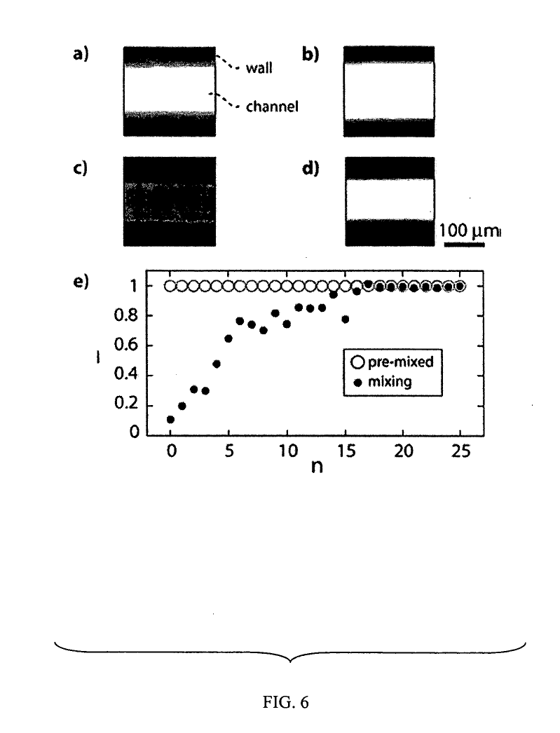

In order to check the compatibility of the mixer with protein chemistry, an enzymatic assay was performed in device 200 (FIG. 7). Aliquots of two solutions were deposited into the sample wells; one solution contained the Amplex red reagent (200 μM H₂O₂, 100 μM Amplex red reagent, in buffer (50 mM sodium phosphate pH 7.4), Molecular Probes, A22188), the other was horseradish peroxidase (HRP) in the same buffer. When mixed together, HRP converts Amplex red into a fluorescent product with an emission maxima at λ≈590 nm. It was observed that intensity of fluorescence obtained was limited by the reaction rate rather than by mixing itself. Using valves (e.g., TWIST valves), the speed of flow through the channels was adjusted to <1 cm/s, which allowed observation of saturation of the fluorescent signal within the mixer (FIG. 6). This experiment shows that the mixer, and other components of device 200, are compatible with protein chemistry.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of” “only one of,” or “exactly one of.” “Consisting essentially of”, when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A mixer constructed and arranged to mix at least a portion of a first and a second fluid component, comprising:
a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system;
fluidically connectable to the inlet channel, a source of the first fluid component, a source of the second fluid component, and a source of at least a first plug defined by a substance immiscible with the first and second fluid components which, when introduced into the inlet channel, causes the first plug to flow into the first or second branch of the second portion,
wherein the mixer is constructed and arranged to mix the first and second fluid components to a greater extent in the outlet channel than in the inlet channel.

2. A mixer as in claim 1, wherein each of the sources in contained in separate containers.

3. A mixer as in claim 1, further comprising a plurality of plugs defined by a substance immiscible with the first and second fluid components.

4. A mixer as in claim 3, wherein the plurality of plugs are constructed and arranged to be positioned in the first or second branches of the second portion, the positioning of the plugs in the first or second branches determined by the positioning of a preceding plug.

5. A mixer as in claim 1, wherein the first and second fluid components are laminar streams of fluid.

6. A mixer as in claim 1, wherein the first and second branches have substantially the same length and/or cross-sectional area.

7. A mixer as in claim 1, wherein the first and second branches have substantially the same resistance to fluid flow in the absence of a plug in the first and second branches.

8. A mixer as in claim 1, wherein the first and second branches have substantially different resistances to fluid flow in the absence of a plug in the first and second branches.

9. A mixer as in claim 1, further comprising a second mixing unit including the third portion comprising a second inlet channel that separates, in a fourth portion downstream of the third portion, into a third branch and a fourth branch, the third and the fourth branches of the fourth portion recombining into a second outlet channel defining a fifth portion of the channel system.

10. A mixer as in claim 9, wherein the third and fourth branches have substantially the same resistance to fluid flow as the first and second branches in the absence of a plug in the first, second, third, and fourth branches.

11. A mixer as in claim 9, wherein the fourth branch is positioned diagonally to the first branch, the first and fourth branches having substantially the same resistance to fluid flow in the absence of a plug in the first and fourth branches, and the third branch is positioned diagonally to the second branch, the second and third branches having substantially the same resistance to fluid flow in the absence of a plug in the second and third branches.

12. A mixer as in claim 1, further comprising a plurality of mixing units.

13. A mixer as in claim 12, wherein plurality comprises at least 6 mixing units.

14. A mixer as in claim 1, wherein the at least two fluid components are laminar streams of fluid.

15. A mixer as in claim 1, wherein the substance comprises a gas immiscible with the at least two fluid components.

16. A mixer as in claim 1, wherein the substance comprises a fluid immiscible with the at least two fluid components.

17. A mixer as in claim 1, wherein the substance comprises a solid immiscible with the at least two fluid components.

18. A mixer as in claim 1, further comprising a plurality of plugs defined by a substance immiscible with the at least two fluid components.

19. A mixer as in claim 1, wherein the first plug positioned in the first branch causes the first branch to have a lower resistance than the second branch.

20. A mixer as in claim 1, further comprising a source of a pressure less than atmospheric pressure fluidically connectable to an outlet of the channel system.

21. A method for mixing at least two fluid components, comprising:
flowing the at least two fluid components in a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system;
flowing a first plug defined by a first substance immiscible with the at least two fluid components in the first branch;
flowing a second plug defined by a second substance immiscible with the at least two fluid components in the second branch, wherein the first and second substances can be the same or different; and
at least in part via enhanced back pressure in either the first or second branch caused at least in part by a plug in one of the respective branches, causing at least a portion of the at least two fluid components to mix in the channel system such that the at least two fluid components are mixed to a greater extent in the outlet channel than in the inlet channel.

22. A method as in claim 21, wherein the at least two fluid components are laminar streams of fluid.

23. A mixer as in claim 21, wherein the first fluid component is flowed at the same flow rate as the second fluid component.

24. A method as in claim 21, wherein flowing is caused at least in part by applying a pressure less than atmospheric pressure to an outlet of the channel system.

25. A method as in claim 21, wherein the first and/or second substances comprises a gas immiscible with the at least two fluid components.

26. A method as in claim 21, further comprising a plurality of mixing units.

27. A method for mixing at least two fluid components, comprising:
flowing the at least two fluid components in a channel system including a first mixing unit comprising a first portion comprising an inlet channel that separates, in a second portion downstream of the first portion, into at least a first branch and a second branch, the first and second branches of the second portion recombining into an outlet channel defining a third portion of the channel system;
changing resistance to fluid flow in the first branch;
changing resistance to fluid flow in the second branch;
wherein changing the resistance to fluid flow in the first and/or second branches causes at least a portion of the at least two fluid components to mix in the channel system; and
whereby the at least two fluid components are mixed to a greater extent in the outlet channel than in the inlet channel.

28. A method as in claim 27, wherein changing resistance to fluid flow in the first or second branches comprises flowing a plug, defined by a substance immiscible with the at least two fluid components, in the first or second branches, respectively.

29. A method as in claim 28, wherein the substance immiscible with the at least two fluid components is a fluid.

30. A method as in claim 28, wherein the fluid is a gas.

31. A mixer as in claim 27, wherein flowing is caused at least in part by applying a pressure less than atmospheric pressure to an outlet of the channel system.
